(19) United States
(12) Patent Application Publication
(10) Pub. No.: US 2008/0116459 A1
(43) Pub. Date: May 22, 2008

(54) Thin film transistor array substrate and method for fabricating same

(75) Inventors: Hung-Yu Chen, Miao-Li (TW); Jia-Pang Pang, Miao-Li (TW)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 11/986,348

(22) Filed: Nov. 21, 2007

(30) Foreign Application Priority Data
Nov. 21, 2006 (TW) 95143002

(51) Int. Cl. H01L 27/12; H01L 21/84

(52) U.S. Cl. 257/59; 438/160; 257/E27.112; 257/E21.7

(57) ABSTRACT

An exemplary TFT array substrate (20) includes: an insulating substrate (201); a common electrode (220), a common line (224), a gate line (23), and a gate electrode (281) arranged on the insulating substrate; a gate insulating layer (204) covering the common electrode, the common line, the gate line, and the gate electrode; a semiconductor layer (207) arranged on the gate insulating layer; a source and a drain electrodes (281, 282) arranged on two ends the semiconductor layer; a passivation material layer (25) covering the gate insulating layer; a pixel electrode arranged on the passivation material layer, the pixel electrode (290) being electrically connected to the drain electrode via a through hole (284); and at least one through channel (225) arranged crossing the gate insulating layer. The at least one through channel are arranged between the common electrode and the gate line, and between the gate line and the common line.

### FIELD OF THE INVENTION

The present invention relates to thin film transistor (TFT) array substrates used in liquid crystal displays (LCDs) and methods for fabricating these substrates; and particularly to a TFT array substrate having at least one isolating element for avoiding the electrical connection between the common electrode, the gate line and the common line, and a method for fabricating the TFT array substrate.

### BACKGROUND

A typical liquid crystal display (LCD) is capable of displaying a clear and sharp image through millions of pixels that make up the complete image. Thus, the liquid crystal display has been applied to various electronic equipments in which messages or pictures need to be displayed, such as mobile phones and notebook computers. A liquid crystal panel is a major component of the LCD, and generally includes a TFT array substrate, a color filter substrate opposite to the TFT array substrate, and a liquid crystal layer sandwiched between the two substrates.

Referring to FIG. 18, part of a conventional TFT array substrate is shown. The TFT array substrate 10 includes a plurality of gate lines 13, a plurality of common lines 14, and a plurality of data lines 17. The gate lines 13 are parallel to but spaced apart from each other. The data lines 17 are parallel to but spaced apart from each other, and are substantially perpendicular to the gate lines 13. Two gate lines 13 and two data lines 17 define a pixel region 100. The common lines 14 are parallel to the gate lines 13, and each of the common lines 14 crosses a pixel region 100.

In each of the pixel region 100, a TFT 180, a pixel electrode 190, and a common electrode 120 are arranged therein. The TFT 180 is arranged at the intersection of the corresponding gate line 13 and the corresponding data line 17. The TFT 180 includes a gate electrode 181, a source electrode 182, and a drain electrode 183.

The pixel and common electrodes 190, 120 are laminated and insulated in the pixel region 100. The pixel and common electrodes 190, 120 are made of transparent conductive materials such as indium-tin-oxide (ITO) or indium-zinc-oxide (IZO). The pixel electrode 190 is electrically connected to the drain electrode 183 of the TFT 180 via a through hole 184, in order to obtain displaying signals therefrom. The common electrode 120 is electrically connected to the common line 14 in order to obtain common voltage signals therefrom.

Referring to FIG. 19, this is a side, cross-sectional view of the TFT array substrate 10 taken along line XIX-XIX. The TFT array substrate 10 further includes a substrate 11, a gate insulating layer 15, a semiconductor layer 107, and a passivation material layer 16. The gate line 13, the common line 14, the gate electrode 181, and the common electrode 120 are arranged at the substrate 11. The gate insulating layer 15 covers the common electrode 120, the gate line 13, the gate electrode 181, and the common line 14. The semiconductor layer 107 is formed on the gate insulating layer 15. The source electrode 182 and the drain electrode 183 are formed on the insulating layer 15 and the semiconductor layer 107 corresponding to the gate electrode 181. The passivation material layer 16 is formed on the gate insulating layer 15, the drain electrode 183 and the source electrode 182. The pixel electrode 190 is formed on the passivation material layer 16, and is electrically connected to the drain electrode 183 via the through hole 184 formed in the passivation material layer 16.

Referring to FIG. 20, this is a flowchart summarizing a conventional method for fabricating the TFT array substrate 10. For simplicity, the flowchart and the following description are couched in terms that relate to the part of the TFT array substrate 10 shown in FIG. 19. The method includes: step S1, forming a transparent conductive layer; step S2, forming a common electrode; step S3, forming a conductive metal layer; step S4, forming a common line, a gate line, and a gate electrode; step S5, forming a gate insulating layer, an amorphous silicon (a-Si) layer, and a doped a-Si layer; step S6, forming a semiconductor layer on the gate insulating layer; step S7, forming a source/drain metal layer; step S8, forming source/drain electrodes; step S9, forming a passivation material layer; step S10, forming a through hole; step S11, forming a transparent conductive layer; step S12, forming a pixel electrode.

In step S1, the insulating substrate 11 is provided. The substrate 11 may be made from glass or quartz. A transparent conductive layer and a first photo-resist layer are sequentially formed on the substrate.

In step S2, the first photo-resist layer is exposed by a first photo-mask, and then is developed, thereby forming a first photo-resist pattern. The transparent conductive layer is etched, thereby forming a pattern of the common electrode 120 according to the first photo-resist pattern. The residual first photo-resist layer is then removed by an acetone solution.

However, in this photolithograph, the transparent conductive layer is etched by wet etching method. If the wet etching process is not precisely controlled, a portion of the transparent conductive layer which is not covered by the photo-resist pattern would not be completely etched, therefore, a residual portion 121 of the transparent conductive layer is easily to be remained.

In step S3, a conductive metal layer and a second photo-resist layer are formed on the substrate 11.

In step S4, the second photo-resist layer is exposed by a second photo-mask, and then is developed, thereby forming a second photo-resist pattern. The conductive metal layer is etched, thereby forming a pattern of the gate electrode 181, the gate line 13, and the common line 14 according to the second photo-resist pattern. The residual first photo-resist layer is then removed by an acetone solution. The residual portion 121 is partially covered by the common line 14 and the gate line 13.

In step S5, the gate insulating layer 15, an a-Si layer, a doped a-Si layer, and a third photo-resist layer are sequentially formed on the substrate 11 and the gate electrode 181.

In step S6, the third photo-resist layer is exposed by a third photo-mask, and then is developed, thereby forming a third photo-resist pattern. The a-Si layer and doped a-Si layer are etched, thereby forming a pattern of the semiconductor layer 107 according to the third photo-resist pattern. The residual third photo-resist layer is then removed by an acetone solution.

In step S7, a source/drain metal layer and a fourth photo-resist layer are sequentially formed on the semiconductor layer 107 and the gate insulating layer 15.

In step S8, the fourth photo-resist layer is exposed by a fourth photo-mask, and then is developed, thereby forming a fourth photo-resist pattern. The source/drain metal layer is etched, thereby forming a pattern of the source electrode 182 and the drain electrode 183 according to the fourth photo-resist pattern. The residual third photo-resist layer is then removed by an acetone solution.

In step S9, the passivation material layer 16 and a fifth photo-resist layer are sequentially formed on the substrate 11 and the TFT 180.

In step S10, the fifth photo-resist layer is exposed by a fifth photo-mask, and then is developed, thereby forming a fifth photo-resist pattern. The passivation material layer 16 is etched, thereby forming a through hole 184 above the drain electrode 183 according to the fifth photo-resist pattern. The residual fourth photo-resist layer is then removed by an acetone solution.

In step S11, a transparent conductive layer and a sixth photo-resist layer are sequentially formed on the passivation material layer 16.

In step S12, the sixth photo-resist layer is exposed by a sixth photo-mask, and then is developed, thereby forming a sixth photo-resist pattern. The transparent conductive layer is etched, thereby forming a pattern of the pixel electrode 190 according to the sixth photo-resist pattern. The pixel electrode 190 is connected to the drain electrode 183 via the through hole 184. The residual sixth photo-resist layer is then removed by an acetone solution.

The above-described method includes six photolithograph processes. In the first photolithograph process, if the transparent conductive layer is not completely etched, a residual portion 121 of the transparent conductive layer is liable to be remained. When the gate line 13 and the common line 14 are formed, the gate line 13 and the common line 14 may cover the residual portion 121. Thus, the residual portion 121 is liable to electrically connect the common electrode 120, the gate line 13, and even produce a short circuit of the common line 14. Moreover, when the TFT array substrate 10 works, a common signal of the common electrode 120 may be interfered by a gate signal of the gate line 13, therefore causing an abnormal display. This decreases a reliability of the TFT substrate 10.

What is needed, therefore, is a method for fabricating a TFT array substrate that can overcome the above-described deficiency. What is also needed is a TFT array substrate fabricated by the above method.

### SUMMARY

In one preferred embodiment, a method for fabricating a thin film transistor (TFT) array substrate includes: providing an insulating substrate; forming a common electrode on the insulating substrate via a first photolithograph process; forming a common line, a gate line, and a gate electrode on the insulating substrate via a second photolithograph process, the gate electrode being connected to the gate line; forming a gate insulating layer and a semiconductor layer on gate insulating layer via a third photolithograph process, the semiconductor layer being above the gate electrode; forming a source/drain electrode on the semiconductor layer via a fourth photolithograph process; forming a passivation material layer and at least one through channel via a fifth photolithograph process, the at least one through channel crossing the passivation material layer, and being arranged between the common electrode and the gate line, and between the gate line and the common line; forming a pixel electrode on the passivation material layer via a sixth photolithograph process.

An exemplary TFT array substrate includes: an insulating substrate; a common electrode, a common line, a gate line, and a gate electrode arranged on the insulating substrate; a gate insulating layer covering the common electrode, the common line, the gate line, and the gate electrode; a semiconductor layer arranged on the gate insulating layer, the semiconductor layer being arranged above the gate electrode; a source and a drain electrodes arranged on two ends the semiconductor layer; a passivation material layer covering the gate insulating layer, the source electrode, and the drain electrode; a pixel electrode arranged on the passivation material layer, the pixel electrode being electrically connected to the drain electrode via a through hole formed in the passivation material layer; and at least one through channel is arranged through the passivation material layer and the gate insulating layer. And the at least one through channel is arranged between the common electrode and the gate line, and/or between the gate line and the common line.

An alternative exemplary TFT array substrate includes: an insulating substrate; a common electrode, a common line, a gate line, and a gate electrode arranged on the insulating substrate; a gate insulating layer covering the common electrode, the common line, the gate line, and the gate electrode; a semiconductor layer arranged on the gate insulating layer, the semiconductor layer being arranged above the gate electrode; a source and a drain electrodes arranged on two ends the semiconductor layer; a passivation material layer covering the gate insulating layer, the source electrode, and the drain electrode; a pixel electrode arranged on the passivation material layer, the pixel electrode being electrically connected to the drain electrode via a through hole formed in the passivation material layer; and at least one isolating element arranged on the substrate. The at least one isolating element is arranged between the common electrode and the gate line, and/or between the gate line and the common line.

Other novel features and advantages will become more apparent from the following detailed description when taken in conjunction with the accompanying drawings. In the drawings, all the views are schematic.

### BRIEF DESCRIPTION OF THE DRAWINGS

FIG. 1 is an abbreviated, top view of part of a TFT array substrate according to an exemplary embodiment of the present invention.

FIG. 2 is a side, cross-sectional view taken along the line II-II of FIG. 1.

FIG. 3 is a flowchart summarizing an exemplary method for fabricating the TFT array substrate of FIG. 1.

FIGS. 4 to 17 are schematic, side cross-sectional views of successive precursors of the part of the TFT array substrate shown in FIG. 1, each view relating to a corresponding one of manufacturing steps of the method of FIG. 3.

FIG. 18 is an abbreviated, top view of part of a conventional TFT array substrate.

FIG. 19 is a side, cross-sectional view of part of the TFT array substrate of FIG. 18.

FIG. 20 is a flowchart summarizing a conventional method for fabricating the TFT array substrate of FIG. 18.

### DETAILED DESCRIPTION OF PREFERRED EMBODIMENTS

Referring to FIG. 1, an abbreviated, top view of part of a TFT array substrate according to an exemplary embodiment of the present invention is shown. The TFT array substrate 20 includes a plurality of gate lines 23, a plurality of common lines 24, and a plurality of data lines 27. The data lines 27 are arranged parallel to each other, and each data line 27 extends along a longitudinal direction. The gate lines 23 are arranged parallel to each other, and each gate line 23 extends along a horizontal direction. Thus, the crossing data lines 27 and gate lines 23 cooperatively define a multiplicity of pixel regions 200. The common lines 24 are parallel to the gate lines 23, and each of the common lines 24 crosses a pixel region 200.

In each pixel region 200, a TFT 280 is provided in the vicinity of a respective point of intersection of one of the gate lines 23 and one of the data lines 27. A comb-shaped pixel electrode 290 and a plate-shaped common electrode 220 are laminated therein. Each TFT 280 has a gate electrode 281 electrically connecting with the gate line 23, a source electrode 282 electrically connecting with the data line 27, and a drain electrode 283 connected to the pixel electrode 290 via a through hole 284. The common line 24 is disposed between the pixel electrode 290 and adjacent gate line 23, and extends along a direction parallel to the gate line 23. And the common line 24 is connected to the common electrode 220 in order to provide common voltage signals thereto. Two through channels 225 are formed at two opposite sides of the gate line 23. One of the through channels 225 is formed between the common electrode 220 and the gate line 23, the other is formed between the gate line 23 and the common line 24.

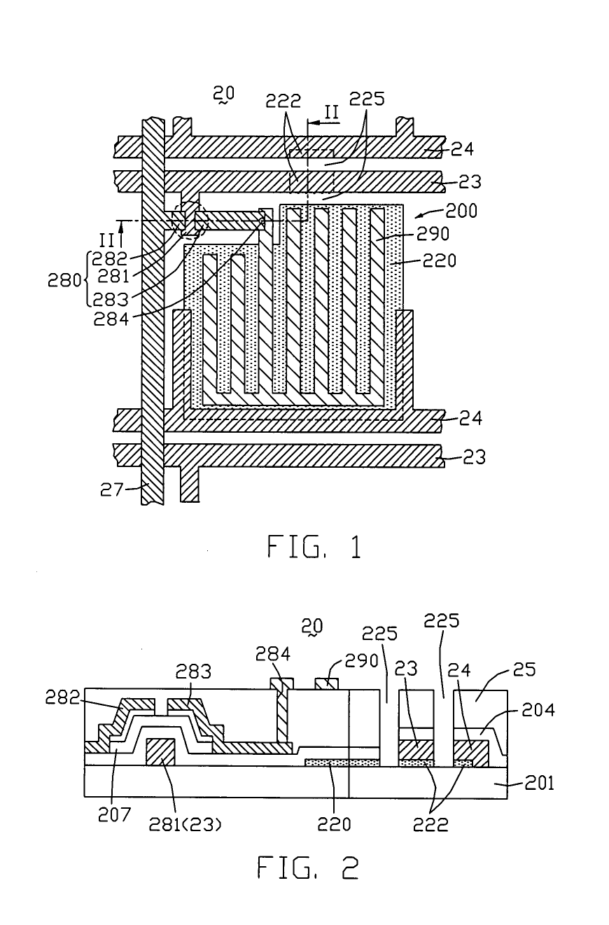

FIG. 2 is a side, cross-sectional view taken along the line II-II of FIG. 1. The TFT array substrate 20 further includes an insulating substrate 201, a gate insulating layer 204, an semiconductor layer 207 and a passivation material layer 25. The gate line 23, the common line 24, the gate electrode 281, and the common electrode 220 are formed on the substrate 201. The gate insulating layer 204 is formed on the gate electrode 281, the common electrode 220, the gate line 23, and the common line 24. The semiconductor layer 207 is formed on the gate insulating layer 204 above the gate electrode 281. The source electrode 282 and the drain electrode 283 are formed on two ends of the semiconductor layer 207 symmetrically. The passivation material layer 25 is formed on the TFT 280 and gate insulating layer 204. The through hole 284 is formed at the passivation material layer 25. The pixel electrode 290 is formed on the passivation material layer 25 and is electrically connected to the drain electrode 283 via the through hole 284. The two through channels 225 are formed through the passivation material layer 25, the gate insulating layer 204, and the residual portion 222, thereby exposing portions of the insulating substrate 201.

The two through channels 225 are arranged there in order to isolate the common electrode 220 and the gate line 23, or the gate line 23 and the common line 24, for cutting of the electrical connection of the common electrode 220 and the gate line 23, or the gate line 23 and the common line 24. Even if a residual portion 222 connecting the common electrode 220, the gate line 23, and the common line 24 may produced in the process of manufacturing, the two through channel 225 can still cut off the residual portion 222. Such that, the two through channels 225 ensures that the common electrode 220 and the gate line 23, or the gate line 23 and the common line 24 are divided and insulated. Accordingly, when the TFT array substrate 20 works, a common signal of the common electrode 220 and a gate signal of the gate line 23 are transmitted and received respectively. Therefore, interference between the common electrode 220 and gate line 23, or between the gate line 23 and the common line 24 is avoid. A reliability of the substrate 20 is increased. The through channel 225 can also be filled with insulating materials, so that the insulating materials function as isolating elements to isolate the common electrode 220, the gate line 23, and the common line 24.

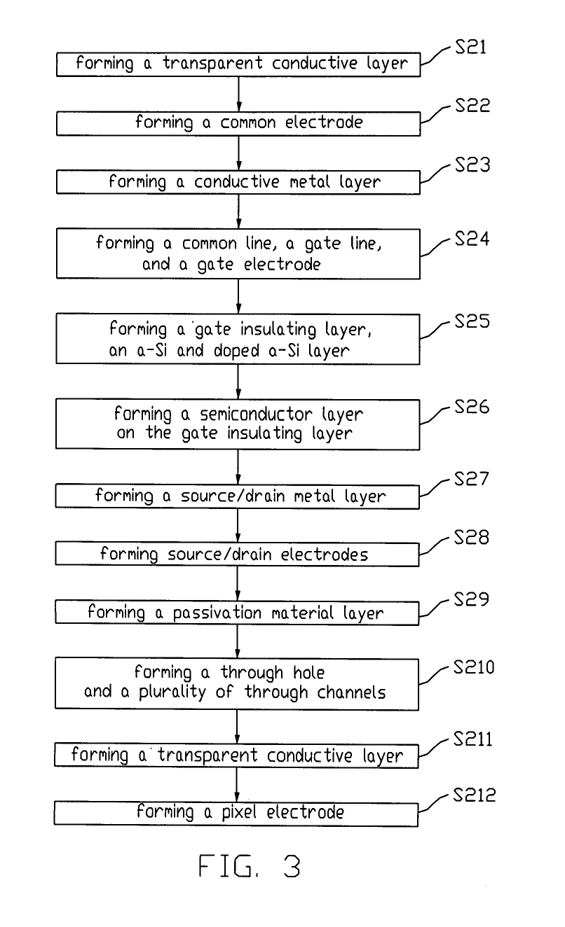

Referring to FIG. 3, this is a flowchart summarizing an exemplary method for fabricating the TFT array substrate 2. For simplicity, the flowchart and the following description are couched in terms that relate to the part of the TFT array substrate 2 shown in FIG. 1. The method includes: step S21, forming transparent conductive layer; step S22, forming a common electrode; step S23, forming a conductive metal layer; step S24, forming a common line, a gate line, and a gate electrode; step S25, forming a gate insulating layer, an a-Si, and a doped a-Si layer; step S26, forming a semiconductor layer on the gate insulating layer; step S27, forming a source/drain metal layer; step S28, forming source/drain electrodes; step S29, forming a passivation material layer; step S210, forming a through hole and a plurality of through channels; step S211, forming a transparent conductive layer; step S212, forming a pixel electrode.

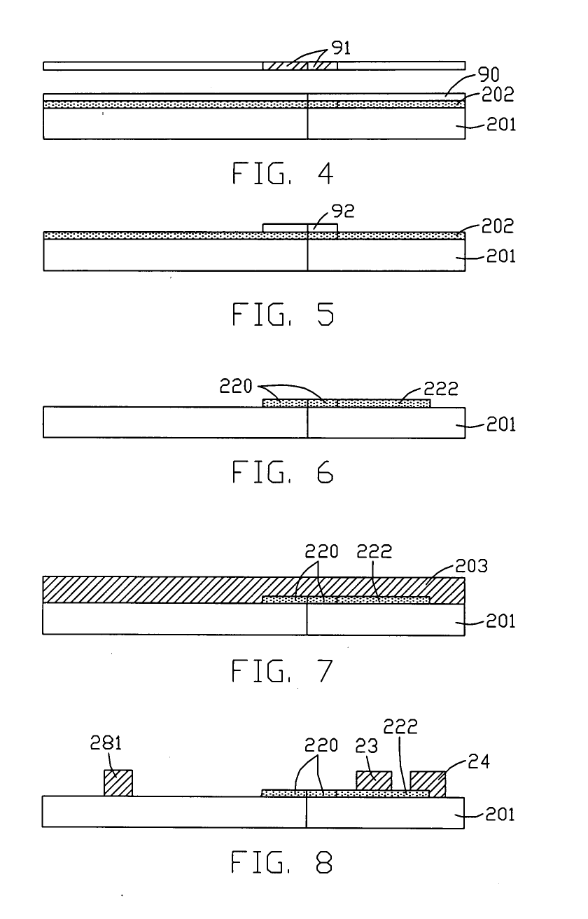

In step S21, referring to FIG. 4, the insulating substrate 201 is provided. The substrate 201 may be made from glass or quartz. A transparent conductive layer 202 and a first photo-resist layer 90 are sequentially formed on the substrate 201. The transparent conductive layer 202 may be Indium Tin Oxide (ITO) or Indium Zinc Oxide (IZO). A photo-mask is also provided above the first photo-resist layer 90.

In step S22, referring to FIG. 5 to FIG. 6, the first photo-resist layer 90 is exposed by the first photo-mask 91, and then is developed, thereby forming a first photo-resist pattern 92. The transparent conductive layer 202 is etched by method of wet etching, thereby forming a pattern of the common electrode 220, which corresponds to the first photo-resist pattern 92. However, if the wet etching is not precisely controlled, a portion of the conductive layer extending from the common electrode 220 may not be completely etched, thereby the residual portion 222 may produced. The first photo-resist pattern 92 is then removed by an acetone solution.

In step S23, referring to FIG. 7, a conductive metal layer 203 and a second photo-resist layer (not shown) are sequentially formed on the substrate 201. The conductive metal layer 203 may be made from material including any one or more items selected from the group consisting of aluminum (Al), molybdenum (Mo), copper (Cu), chromium (Cr), and tantalum (Ta).

In step S24, referring to FIG. 8, the second photo-resist layer is exposed by a second photo-mask (not shown), and then is developed, thereby forming a second photo-resist pattern (not shown). A portion of the conductive metal layer 203 is etched, thereby forming a pattern of the gate electrode 281, the gate line 23, and the common line 24, which corresponds to the second photo-resist pattern. The gate electrode 281 and the gate line 23 are incorporated. The residual second photo-resist layer is then removed by an acetone solution. The residual portion 222 is partially covered by the common line 24 and the gate line 23. Thus, the residual portion 222 electrically connects with the common electrode 220, the gate line 23, and the common line 24.

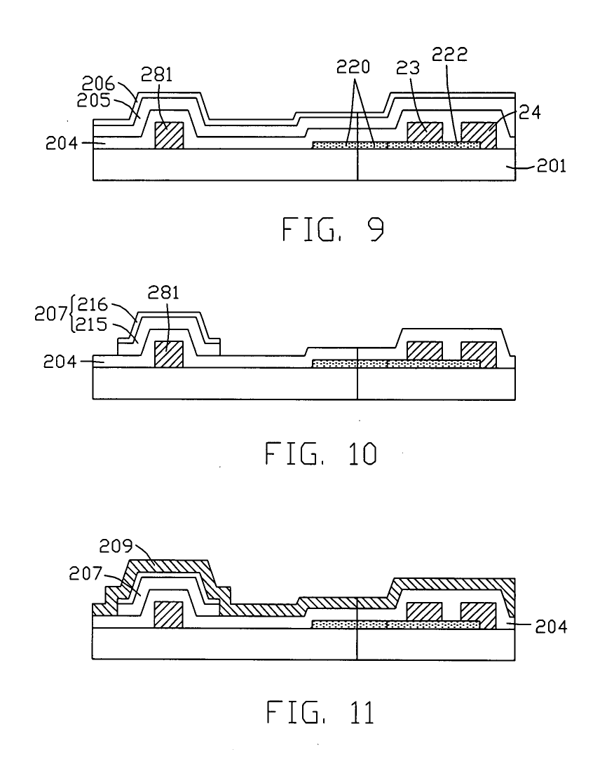

In step S25, referring to FIG. 9, the gate insulating layer 204 is formed on the substrate 201 having the gate electrode 281, the common electrode 220, the gate line 23, and the common line 24 by a chemical vapor deposition (CVD) process. In this process, silane (SiH4) reacts with alkaline air (NH4+) to obtain silicon nitride (SiNx), a material of the gate insulating layer 204. An a-Si layer 205 is deposited on the gate insulating layer 204 by a CVD process. A top layer of the a-Si layer 205 is doped, thereby forming a doped a-Si layer 206. Then a third photo-resist layer (not shown) is formed on the doped a-Si layer 206.

In step S26, referring to FIG. 10, An ultra violet (UV) light source and a photo-mask (not shown) are used to expose the third photo-resist layer. Then the exposed third photo-resist layer is developed, thereby forming a second photo-resist pattern. Using the third photo-resist pattern as a mask, portions of the doped a-Si layer 206 and the a-Si layer 205 which are not covered by the third photo-resist pattern are etched away, thereby forming an a-Si pattern 215 and a doped a-Si pattern 216. The a-Si pattern 215 and the doped a-Si pattern 216 cooperatively define the semiconductor layer 207. The residual third photo-resist layer is then removed by an acetone solution.

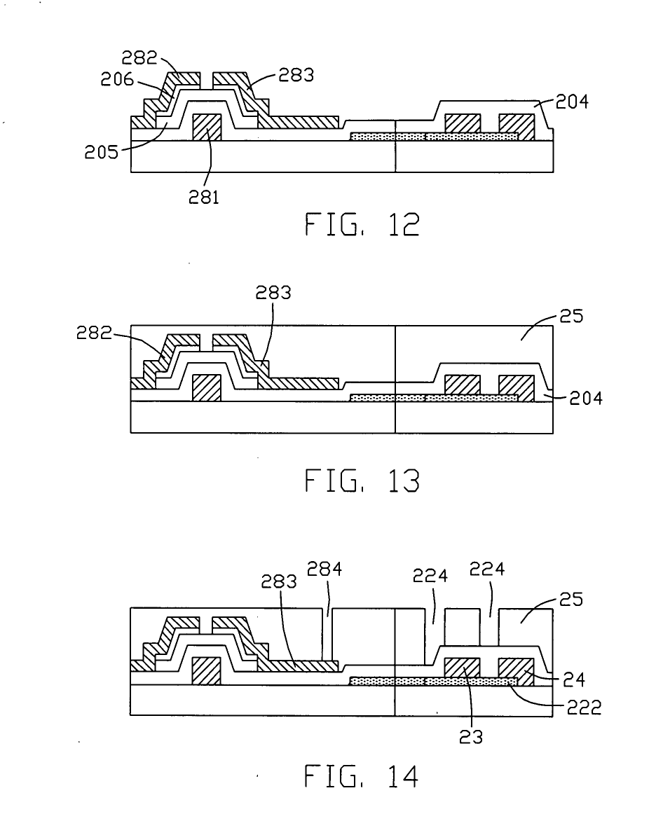

In step S27, referring to FIG. 11, a source/drain metal layer 209 is then deposited on the semiconductor layer 207 and the gate insulating layer 204. The source/drain metal layer 209 may be made from material including any one or more items selected from the group consisting of aluminum, aluminum alloy, molybdenum, tantalum, and molybdenum-tungsten alloy. Then a fourth photo-resist layer (not shown) is formed on the source/drain metal layer 209.

In step S28, referring to FIG. 12, the fourth photo-resist layer is exposed by a fourth photo-mask (not shown), and then is developed, thereby forming a fourth photo-resist pattern. The source/drain metal layer 209 is etched, thereby forming a pattern of the source/drain electrodes 282, 283, which are formed on two ends of the semiconductor layer 207 symmetrically. Using the source/drain metal electrodes 282, 283 as a mask, portions of the doped a-Si pattern 206 which are not covered by the source/drain metal pattern 217 are etched away, thereby departing the doped a-Si pattern 206 into two parts. The residual fourth photo-resist layer is then removed by an acetone solution.

In step S29, referring to FIG. 13, the passivation material layer 25 and a fifth photo-resist layer (not shown) are sequentially formed on the source/drain electrodes 282, 283 and the gate insulating layer 204. The passivation material layer 25 is made from silicon nitride (SiNx) or silicon oxide (SiOx).

In step S210, referring to FIG. 14, the fifth photo-resist layer is exposed by a fifth photo-mask (not shown), and then is developed, thereby forming a fifth photo-resist pattern. A portion of the passivation material layer 25 is etched, thereby forming the through hole 284 and a plurality of channels 224 in the passivation material layer 25. The through hole 284 is above the drain electrode 283, in order to expose a portion of the drain electrode 283. The channels 224 are formed above the residual portion 222 where is not covered by the gate line 23 and the common line 24.

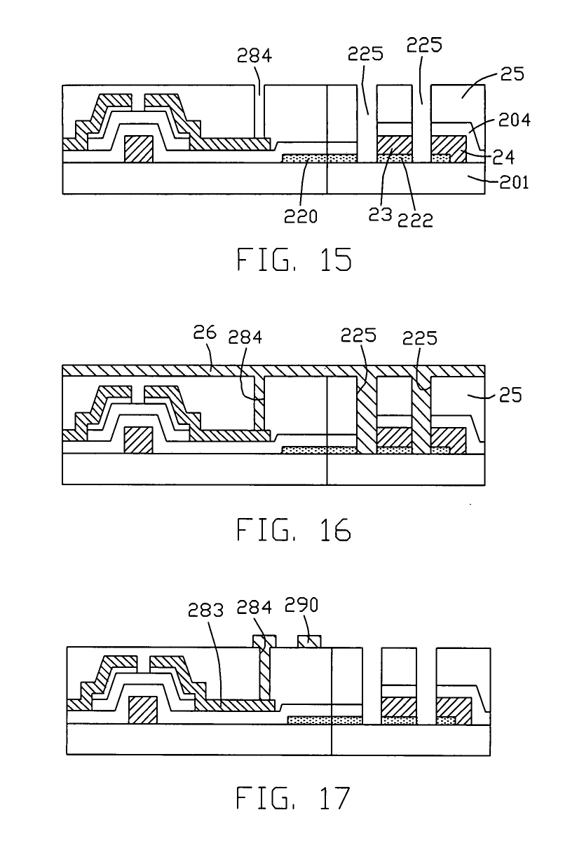

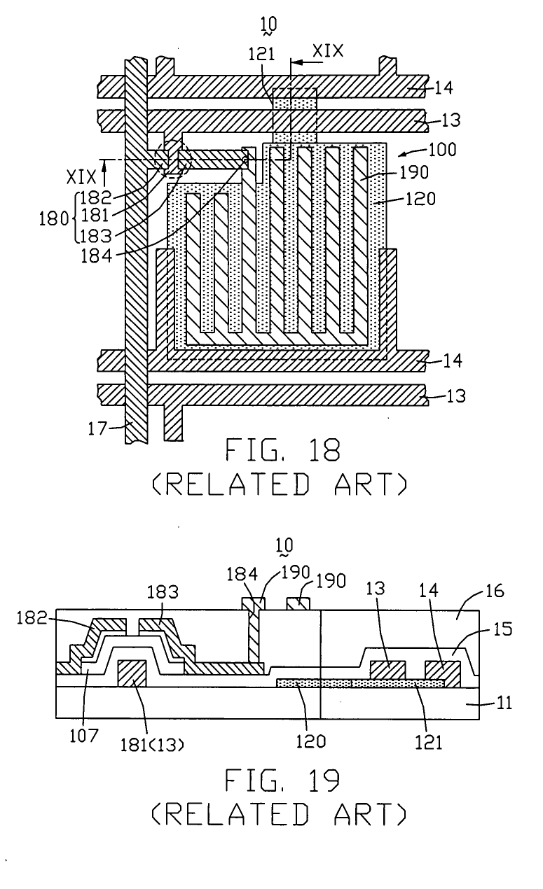

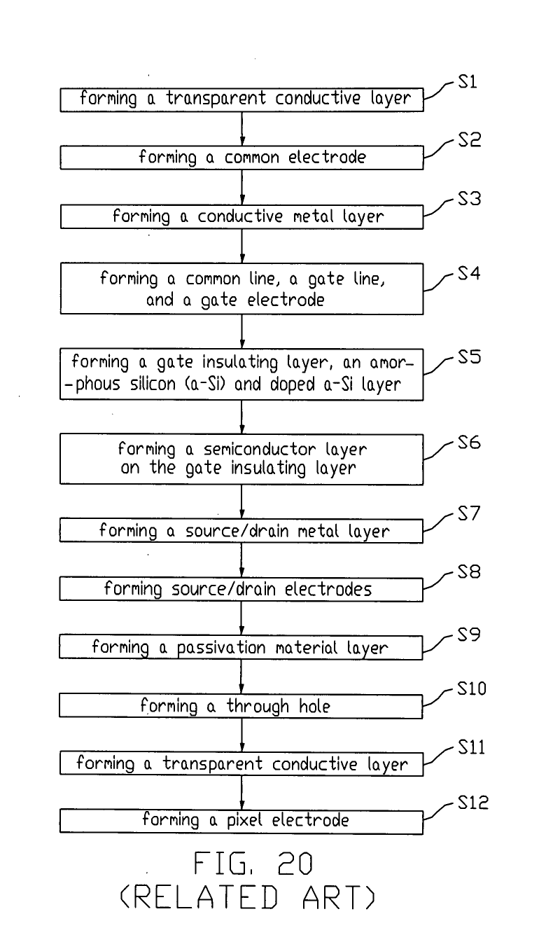

Also referring to FIG. 15, a portion of the gate insulating layer 204 and a portion of the residual portion 222 which are under the channels 223 are etched away to expose portions of the substrate 201; thereby forming a plurality of through channels 225. The through channels 225 depart the residual portion 222 into some fragments, such that the electrical connection of the common electrode 220 and the gate line 23, or the gate line 23 and the common line 24 is departed, and insulating the common electrode 220 and the gate line 23, or the gate line 23 and the common line 24.

In step S211, referring to FIG. 16, a transparent conductive layer 26 and a sixth photo-resist layer (not shown) are sequentially formed on the passivation material layer 25. The transparent conductive layer 26 fills the through hole 284 and the through channels 225.

In step S212, referring to FIG. 17, the sixth photo-resist layer is exposed by a sixth photo-mask (not shown), and then is developed, thereby forming a sixth photo-resist pattern. A portion of the transparent conductive layer 26 including the portion in the through channels 225 is etched away, thereby forming a pattern of the pixel electrode 290. which corresponds to the sixth photo-resist pattern. The pixel electrode 290 is electrically connected the drain electrode 283 via the though hole 284. The residual sixth photo-resist layer is then removed by an acetone solution.

In summary, compared to the above-described conventional method, in sixth photolithograph processes of the above-described exemplary method for fabricating the TFT array substrate 20, two through channels 255 are formed between the common electrode 220 and the gate line 23, and between the gate line 23 and the common line 24, thereby to separate the common electrode 220 and the gate line 23, or the gate line 23, and the common line 24. Even if a residual portion 222 of the common electrode 220 is formed in the process of the manufacturing, producing electrical connection between the common electrode 220 and the gate line 23, or the gate line 23 and the common line 24, the residual portion 222 can be divided into several fragments. Such that the common electrode 220, the gate line 23, and the common line 24 are seperated and insulated in order to avoid a short circuit. Thus, interference between a gate signal of the gate line 23 and a common signal of the common electrode 220 is eliminated. This increases a reliability of the TFT array substrate 20. Furthermore, the through channels 225 can be formed together with the through hole 284 through the fifth photolithograph process. An additional photolithography process is needless, and a production efficiency of the TFT array substrate 20 is increased.

It is to be understood, however, that even though numerous characteristics and advantages of the present embodiments have been set out in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A method for fabricating a thin film transistor (TFT) array substrate, the method comprising:
providing an insulating substrate;
forming a common electrode on the insulating substrate via a first photolithograph process;
forming a common line, a gate line, and a gate electrode on the insulating substrate via a second photolithograph process, the gate electrode being connected to the gate line;
forming a gate insulating layer and a semiconductor layer on the gate insulating layer via a third photolithograph process, the semiconductor layer being above the gate electrode;
forming a source/drain electrode on the semiconductor layer via a fourth photolithograph process;
forming a passivation material layer and at least one through channel via a fifth photolithograph process, the at least one through channel through the passivation material layer and the gate insulating layer, and being arranged between the common electrode and the gate line, and between the gate line and the common line;
forming a pixel electrode on the passivation material layer via a sixth photolithograph process.

2. The method as claimed in claim 1, wherein the common line is parallel to and adjacent to the gate line.

3. The method as claimed in claim 2, wherein the sixth photolithograph process comprises forming a first and a second through channels, the first through channel insulates the common electrode and the gate line, the second through channel insulates the gate line and the common line.

4. The method as claimed in claim 1, wherein the common line is connected to the common electrode in order to provide common voltage signals thereto.

5. The method as claimed in claim 1, wherein the fifth photolithograph process comprises coating a photo-resist layer on the insulating substrate on the passivation material layer, exposing the photo-resist layer using a photo-mask, and developing the exposed photo-resist layer to form a photo-resist pattern.

6. The method as claimed in claim 5, wherein the fifth photolithograph process further comprises etching the passivation material layer which is above the drain electrode, thereby forming a through hole therein.

7. The method as claimed in claim 6, wherein the drain electrode is electrically connected to the pixel electrode via the through hole.

8. The method as claimed in claim 5, wherein the fifth photolithograph process further comprises etching away a portion of the passivation material layer and a portion of the gate insulating layer, thereby forming a first through channel to expose the insulating substrate, the first though channel electrically dividing the common electrode and the gate line.

9. The method as claimed in claim 8, wherein the fifth photolithograph process further comprises etching away a portion of the passivation material layer and a portion of the gate insulating layer, thereby forming a second through channel to expose the insulating substrate, the first through channel electrically dividing the gate line and the common line.

10. The method as claimed in claim 1, wherein the substrate is made from glass or quartz.

11. The method as claimed in claim 1, wherein the common electrode and pixel electrode are made from indium tin oxide or indium zinc oxide.

12. The method as claimed in claim 1, wherein the gate electrode, the gate line, and the common line are made from material including any one or more items selected from the group consisting of aluminum, molybdenum, copper, chromium, and tantalum.

13. The method as claimed in claim 1, wherein the source/drain electrodes are made from material including any one or more items selected from the group consisting of aluminum, aluminum alloy, molybdenum, tantalum, and molybdenum-tungsten alloy.

14. A thin film transistor array substrate comprising:
an insulating substrate;
a common electrode, a common line, a gate line, and a gate electrode arranged on the insulating substrate;
a gate insulating layer covering the common electrode, the common line, the gate line, and the gate electrode;
a semiconductor layer arranged on the gate insulating layer, the semiconductor layer being above the gate electrode;
a source and a drain electrodes arranged on two ends the semiconductor layer;
a passivation material layer covering the gate insulating layer, the source electrode, and the drain electrode; and
a pixel electrode arranged on the passivation material layer, the pixel electrode being electrically connected to the drain electrode via a through hole formed in the passivation material layer;
wherein at least one through channel is arranged through the passivation material layer and the gate insulating layer, and is arranged between the common electrode and the gate line, and/or between the gate line and the common line.

15. The thin film transistor array substrate as claimed in claim 14, wherein the at least one through channel comprises a first through channel and a second through channel, the first through channel is arranged between the common electrode and the gate line, the second through channel is arranged between the gate line and the common line.

16. The thin film transistor array substrate as claimed in claim 14, wherein the common line is electrically connected to the common electrode in order to provide common voltage signals thereto.

17. A thin film transistor array substrate comprising:
an insulating substrate;
a common electrode, a common line, a gate line, and a gate electrode arranged on the insulating substrate;
a gate insulating layer covering the common electrode, the common line, the gate line, and the gate electrode;
a semiconductor layer arranged on the gate insulating layer, the semiconductor layer being above the gate electrode;
a source and a drain electrodes arranged on two ends the semiconductor layer;
a passivation material layer covering the gate insulating layer, the source electrode, and the drain electrode; and
a pixel electrode arranged on the passivation material layer, the pixel electrode being electrically connected to the drain electrode via a through hole formed in the passivation material layer;
wherein at least one isolating element is arranged on the substrate, the at least one isolating element is arranged between the common electrode and the gate line, and/or between the gate line and the common line.

18. The thin film transistor array substrate as claimed in claim 17, wherein the at least one isolating element comprises a first isolating element and a second isolating element, the first isolating element is arranged between the common electrode and the gate line, the second isolating element is arranged between the gate line and the common line.

19. The thin film transistor array substrate as claimed in claim 17, wherein the at least one isolating element is at least one through channel.
